(19) United States
(12) Patent Application Publication
(10) Pub. No.: US 2024/0319573 A1
(43) Pub. Date: Sep. 26, 2024

(54) PROJECTION DEVICE

(71) Applicant: Coretronic Corporation, Hsin-Chu (TW)

(72) Inventors: Te-Ying Tsai, Hsin-Chu (TW); Jia-Hong Dai, Hsin-Chu (TW); Tsung-Han Lin, Hsin-Chu (TW); Shao-Peng Su, Hsin-Chu (TW); Po-Hao Su, Hsin-Chu (TW)

(73) Assignee: Coretronic Corporation, Hsin-Chu (TW)

(21) Appl. No.: 18/611,724

(22) Filed: Mar. 21, 2024

(30) Foreign Application Priority Data
Mar. 23, 2023 (CN) 202310289156.5

(51) Int. Cl. G03B 21/16; G02B 26/00; G03B 21/20; H05K 7/20

(52) U.S. Cl. CPC G03B 21/16; G02B 26/008; G03B 21/204; H05K 7/20154; H05K 7/20263; H05K 7/20272

(57) ABSTRACT

A projection device includes a housing, and a light source module, an optical engine module, a liquid cooling module, a first fan group and a projection lens disposed in an accommodating space. A light emitting side plate, an air outlet side plate, and a first and a second side plate surround the accommodating space. The air outlet side plate has an air outlet, and at least one of the light emitting side plate, and the first and the second side plate has at least one air inlet. The liquid cooling module includes a heat exchanger. The first fan group is located between the heat exchanger and the air outlet. An orthographic projection area of the cooling fin set of the heat exchanger on the air outlet side plate is smaller than or equal to an orthographic projection area of the first fan group on the air outlet side plate.

### CROSS-REFERENCE TO RELATED APPLICATION

This application claims the priority benefit of China application serial no. 202310289156.5, filed on Mar. 23, 2023. The entirety of the above-mentioned patent application is hereby incorporated by reference herein and made a part of this specification.

### BACKGROUND

### Technical Field

The disclosure relates to an optical device, and in particular relates to a projection device.

### Description of Related Art

In existing solid-state light source projectors, a radiator and a group of radiator fans are disposed at the air inlet of the system. Due to the large flow resistance of the radiator and the consideration of system resistance, a group of system fans is usually disposed at the air outlet of the system, and a series flow field is formed between the system fans and the radiator fans to achieve better flow and noise performance. However, since other air inlets of the system are still equipped with fans to dissipate heat from the heating elements, the system fans located at the air outlet are required to increase the fan speed to maintain the flow of the radiator, which increases the system noise. In addition to the air inlet provided with a radiator, the air inlet of other components must be added, and a larger air inlet area also results in a larger system volume.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

A projection device is provided in the invention, in which the projection device may have better cooling effect and image quality.

The other objectives and advantages of the present invention may be further understood from the descriptive features disclosed in the present invention.

In order to achieve one of, or portions of, or all of the above objectives or other objectives, an embodiment of the present invention provides a projection device, which includes a housing, a light source module, an optical engine module, a liquid cooling module, a first fan group, and a projection lens. The housing includes a light emitting side plate, an air outlet side plate, a first side plate, and a second side plate. The light emitting side plate, the air outlet side plate, the first side plate, and the second side plate surround the accommodating space. The light source module, the optical engine module, the liquid cooling module, the first fan group, and at least a portion of the projection lens are disposed in the accommodating space. The projection lens is disposed on the light emitting side plate, and the air outlet side plate has an air outlet. At least one of the light emitting side plate, the first side plate, and the second side plate has at least one air inlet. The liquid cooling module includes a heat exchanger, and the heat exchanger is adjacent to the air outlet of the air outlet side plate and includes a cooling fin set. The first fan group is located between the heat exchanger and the air outlet. An orthographic projection area of the cooling fin set of the heat exchanger on the air outlet side plate is smaller than or equal to an orthographic projection area of the first fan group on the air outlet side plate.

Based on the above, the embodiments of the present invention have at least one of the following advantages or effects. In the design of the projection device of the present invention, the heat exchanger of the liquid cooling module is adjacent to the air outlet of the air outlet side plate and includes a cooling fin set. The first fan group is located between the heat exchanger and the air outlet, and the orthographic projection area of the cooling fin set of the heat exchanger on the air outlet side plate is smaller than or equal to the orthographic projection area of the first fan group on the air outlet side plate. With this design, it may ensure that the air volume entering the projection device passes through the cooling fin set of the heat exchanger before being discharged out of the projection device, so that the cooling fin set may obtain the maximum air volume of the system for cooling. Therefore, the projection device of the present invention may have better cooling effect, and thereby may have better image quality.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top schematic diagram of a projection device according to an embodiment of the present invention.

FIG. 1B is a rear perspective schematic diagram of FIG. 1A.

FIG. 1C is a three-dimensional schematic diagram of the liquid cooling module in FIG. 1A.

FIG. 1D is a schematic diagram of the optical path of the projection device in FIG. 1A.

FIG. 2A is a top schematic diagram of a projection device according to another embodiment of the present invention.

FIG. 2B is a rear schematic diagram of FIG. 2A.

FIG. 2C is a three-dimensional schematic diagram of the light source module in FIG. 2A.

FIG. 3 is a top schematic diagram of a projection device according to another embodiment of the present invention.

FIG. 4 is a top schematic diagram of a projection device according to another embodiment of the present invention.

### DETAILED DESCRIPTION OF DISCLOSED EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention may be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

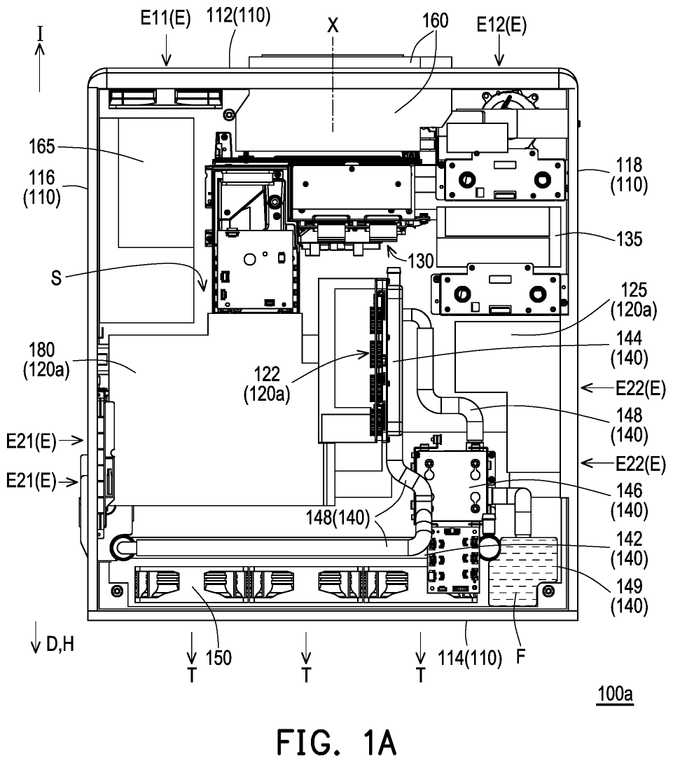

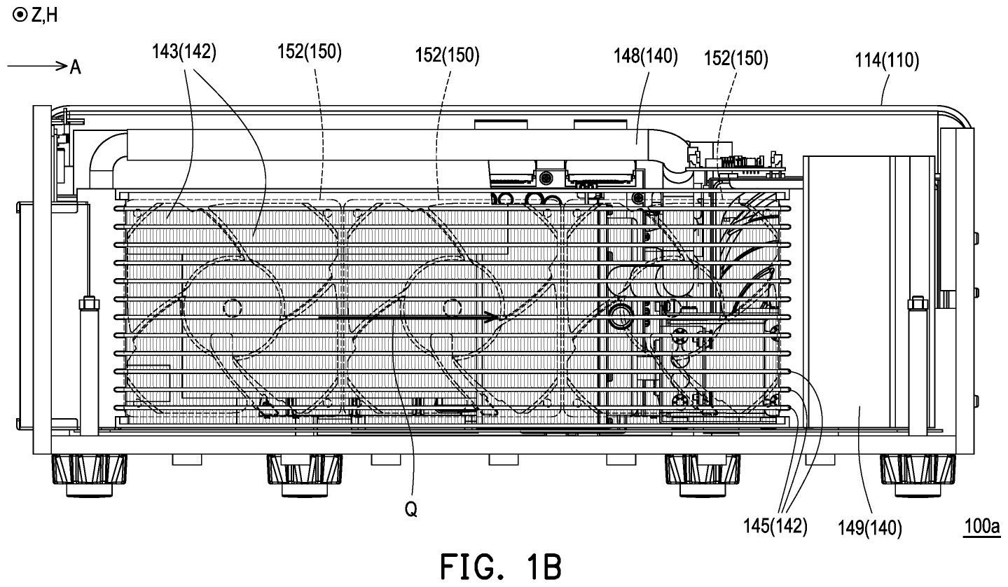

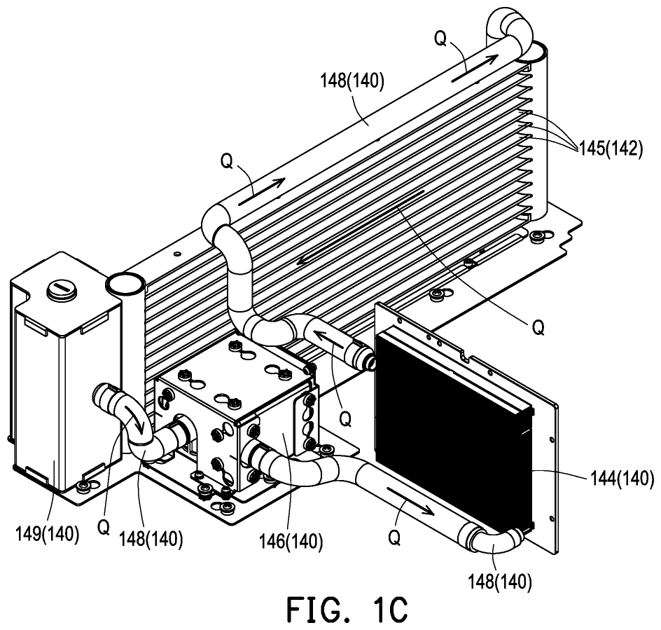

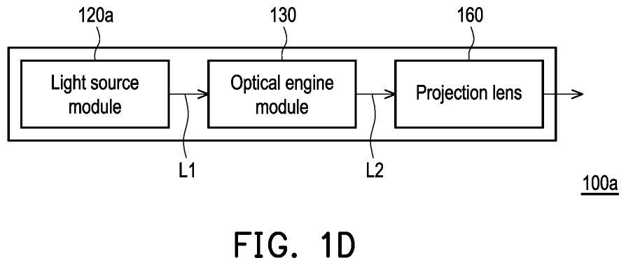

FIG. 1A is a top schematic diagram of a projection device according to an embodiment of the present invention. FIG. 1B is a rear perspective schematic diagram of FIG. 1A. FIG. 1C is a three-dimensional schematic diagram of the liquid cooling module in FIG. 1A. FIG. 1D is a schematic diagram of the optical path of the projection device in FIG. 1A. For convenience of description, the first fan group in FIG. 1B is shown by a dashed line, and the cooling fin set is omitted in FIG. 1C.

Referring to FIG. 1A and FIG. 1B at the same time, in this example, a projection device 100a includes a housing 110, a light source module 120a, an optical engine module 130, a liquid cooling module 140, a first fan group 150, and a projection lens 160. The housing 110 includes a light emitting side plate 112, an air outlet side plate 114, and a first side plate 116 and a second side plate 118 connected to the light emitting side plate 112 and the air outlet side plate 114. The light emitting side plate 112, the air outlet side plate 114, the first side plate 116, and the second side plate 118 surround the accommodating space S. The light source module 120a, the optical engine module 130, the liquid cooling module 140, the first fan group 150, and at least a portion of the projection lens 160 are disposed in the accommodating space S. The projection lens 160 is disposed on the light emitting side plate 112, and the air outlet side plate 114 has an air outlet T. At least one of the light emitting side plate 112, the first side plate 116, and the second side plate 118 has at least one air inlet E. The air outlet direction D of the air outlet T is parallel to and opposite to the light emitting direction I of the projection lens 160. The liquid cooling module 140 includes a heat exchanger 142, and the heat exchanger 142 is adjacent to the air outlet T of the air outlet side plate 114 and includes a cooling fin set 143. The first fan group 150 is located between the heat exchanger 142 and the air outlet T, that is, the first fan group 150 is located between the cooling fin set 143 and the air outlet T. An orthographic projection area of the cooling fin set 143 of the heat exchanger 142 on the air outlet side plate 114 is smaller than or equal to an orthographic projection area of the first fan group 150 on the air outlet side plate 114.

More specifically, referring to FIG. 1A again, in this embodiment, there are multiple air inlets E, including two first air inlets E11 and E12, and multiple second air inlets E21 and E22. The first air inlets E11 and E12 are provided with the light emitting side plate 112 and are respectively located on two sides of the projection lens 160. The second air inlet E21 is disposed on the first side plate 116, and the second air inlet E22 is disposed on the second side plate 118. Preferably, the area of the first air inlets E11 and E12 plus the area of the second air inlets E21 and E22 is greater than the area of the air outlet T.

As shown in FIG. 1D, the light source module 120a of this embodiment is configured to provide an illumination beam L1. The light source module 120 used in this embodiment includes one or more light emitting elements 122, and the light emitting elements 122 are, for example, one or more laser diodes (LD), one or more light emitting diodes (LED) or a combination of the above two light sources. Specifically, any light source that meets the volume requirement in actual design may be implemented, and the present invention is not limited thereto. The optical engine 130 is disposed on the transmission path of the illumination beam L1 and configured to convert the illumination beam L1 into an image light beam L2. The optical engine module 130 may include a light valve, and the light valve is, for example, a reflective light modulator such as a liquid crystal on silicon plate (LCoS plate), a digital micro-mirror device (DMD), or the like. In one embodiment, the light valve is, for example, a transparent liquid crystal plate, an electro-optical modulator, a magneto-optical modulator, an acousto-optic modulator (AOM), and other transmissive optical modulators, but this embodiment does not limit the form and type of the light valve. The detailed process and implementation for the light valve of the optical engine module 130 to convert the illumination beam L1 into the image light beam L2 may be obtained from general knowledge in the technical field with sufficient teaching, suggestion and implementation description, and therefore will not be repeated. The projection lens 160 is disposed on the transmission path of the image light beam L2 and configured to project the image light beam L2 out of the projection device 100a. The projection lens 160 includes, for example, a combination of one or more optical lenses with diopter, such as various combinations of non-planar lenses such as biconcave lenses, biconvex lenses, meniscus lenses, convex-concave lenses, plano-convex lenses, and plano-concave lenses. In an embodiment, the projection lens 160 may also include a flat optical lens to convert the image light beam L2 from the light valve into a projection light beam by reflection or transmission, which is then projected out of the projection device 100a. Herein, in this embodiment, the form and type of the projection lens 160 are not limited.

Referring to FIG. 1A again, the light source module 120a of the projection device 100a in this embodiment further includes a light source driver 125 and a wheel module 180, which are disposed in the accommodating space S. The light source driver 125 is connected to the light emitting element 122 of the light source module 120a. Here, the light source driver 125 is adjacent to the second side plate 118. In addition, the wheel module 180 is disposed beside the first side plate 116 and corresponds to the second air inlet E21 of the first side plate 116. Furthermore, the projection device 100a of this embodiment further includes an optical engine cooling module 135 disposed in the accommodating space S and connected to the optical engine module 130. The optical engine cooling module 135 is located between the projection lens 160 and the second side plate 118, and is adjacent to the first air inlet E12.

Referring to FIG. 1A, FIG. 1B, and FIG. 1C at the same time, in this embodiment, the liquid cooling module 140 further includes a liquid cooling plate 144, a driving element 146, and multiple pipes 148. The heat exchanger 142, the liquid cooling plate 144, and the driving element 146 are connected to each other by multiple pipes 148 to form a loop. Here, the liquid cooling plate 144 is disposed adjacent to the light emitting element 122 of the light source module 120a to transfer the heat generated by the light emitting element 122 to the heat exchanger 142 through the loop formed by the pipe 148. In another embodiment, the liquid cooling plate 144 may also be disposed adjacent to the optical engine module 130 to transfer the heat generated by the optical engine module 130 to the heat exchanger 142 through the loop formed by the pipe 148. The liquid cooling plate 144 is, for example, adjacent to heat generating elements disposed in the projection device 100a, such as the light emitting element 122 of the light source module 120a or the light valve of the optical engine module 130, but not limited thereto. Furthermore, the liquid cooling module 140 of this embodiment further includes an accommodating tank 149 connected to the pipes 148 and the driving element 146, and configured to accommodate the liquid medium F. The liquid medium F in the accommodating tank 149 is transferred into the pipes 148 through the driving element 146. Here, the driving element 146 is, for example, a pump, but not limited thereto. In addition, the heat exchanger 142 of this embodiment further includes at least one liquid flow pipe (multiple liquid flow pipes 145 are schematically shown), disposed in the cooling fin set 143. The pipes 148 are connected to the liquid flow pipe 145 of the heat exchanger 142 to form a loop, so that the liquid medium F is transferred in the loop formed by the pipes 148 and the liquid flow pipe 145 of heat exchanger 142. The liquid flow pipes 145 are arranged at intervals and alternately arranged with multiple columns of cooling fins of the cooling fin set 143.

Referring to FIG. 1A and FIG. 1B at the same time again, the orthographic projection area of the first fan group 150 on the air outlet side plate 114 in this embodiment is equal to the area of the air outlet T. The first fan group 150 includes, for example, three fans 152, and the fans 152 are arranged along a direction A with the air outlet region facing the air outlet side plate 114. The fans 152 of the first fan group 150 may be, for example, axial flow fans, and the axial direction Z of at least one axial flow fan is parallel to the cooling air flow direction H of the cooling fin set 143, while the liquid flow direction Q of the liquid flow pipe 145 is perpendicular to the axial direction Z of at least one axial flow fan.

In addition, referring to FIG. 1A again, the optical axis X of the projection lens 160 in this embodiment corresponds to the center point of the light emitting side plate 112 of the housing 110. The projection device 100a may further include a power module 165 disposed in the accommodating space S. The power module 165 is located between the projection lens 160 and the first side plate 116, and is adjacent to the first air inlet E11 disposed on the light emitting side plate 112.

It is worth mentioning that, in a simulation experiment, under the same air volume, compared with existing solid-state light source projectors, the projection device 100a of this embodiment may have a lower fan speed, which may reduce noise by about 5 dB(A). In addition, the projection device 100a of this embodiment may also reduce the system volume by 25% under the brightness performance similar to that of existing solid-state light source projectors.

In short, the heat exchanger 142 of the liquid cooling module 140 in this embodiment is adjacent to the air outlet T of the air outlet side plate 114. The first fan group 150 is located between the heat exchanger 142 and the air outlet T. The orthographic projection of the cooling fin set 143 of the heat exchanger 142 on the air outlet side plate 114 is located on the orthographic projection of the first fan group 150 on the air outlet side plate 114, and the orthographic projection area of the cooling fin set 143 of the heat exchanger 142 on the air outlet side plate 114 is smaller than or equal to the orthographic projection area of the first fan group 150 on the air outlet side plate 114. With this design, it may ensure that the air volume entering the projection device 100a passes through the cooling fin set 143 of the heat exchanger 142 before being discharged out of the projection device 100a, so that the cooling fin set 143 may obtain the maximum air volume of the system for cooling. That is to say, the aforementioned design may increase the cooling efficiency of the heat exchanger 142, so the projection device 100a of this embodiment may have better cooling effect, and thereby may have better image quality. Furthermore, through the optimized area design of the cooling fin set 143 of the heat exchanger 142, the air outlet T and the air inlet E, the system volume of the projection device 100a of this embodiment may be effectively reduced. In addition, since the air outlet direction D of the air outlet T in this embodiment is parallel to and opposite to the light emitting direction I of the projection lens 160, and the air outlet region of the air outlet T is on the side distant from the projection lens 160, it is possible to avoid the problem that the air temperature of the air inlet located at the air outlet is too high due to the adjacent air outlet when the projection systems are placed side by side laterally when multiple projection devices 100a are implementing image blending, which causes the system to easily overheat.

Other embodiments are described below for illustrative purposes. It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

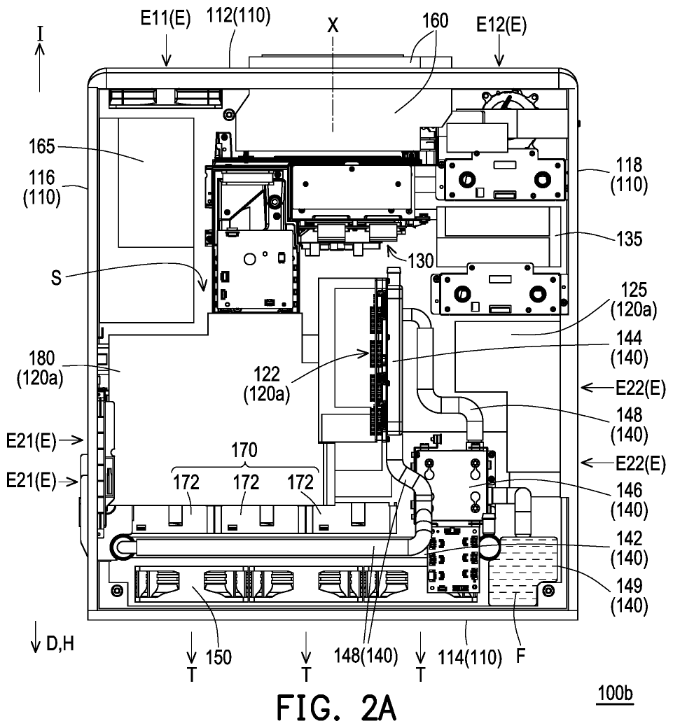

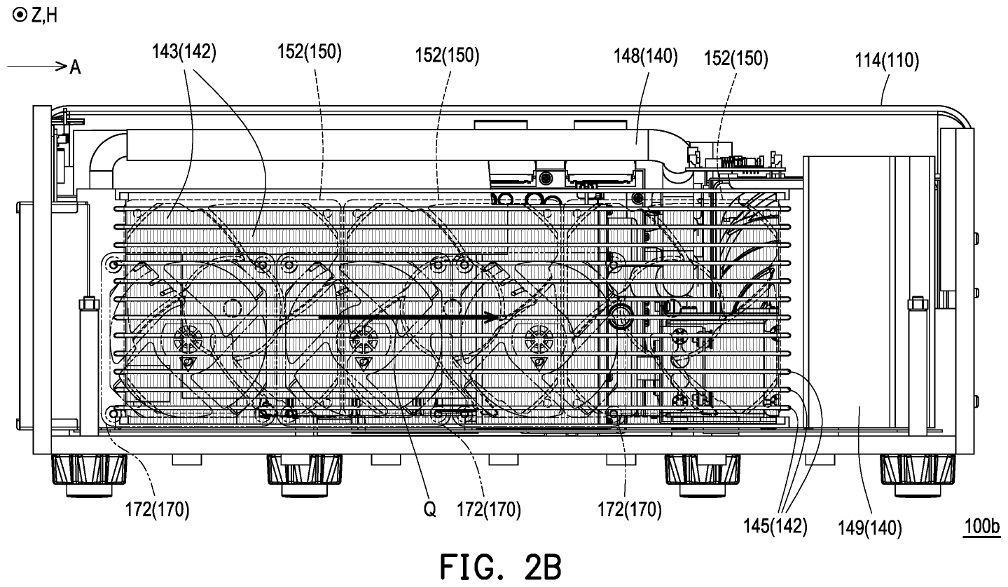

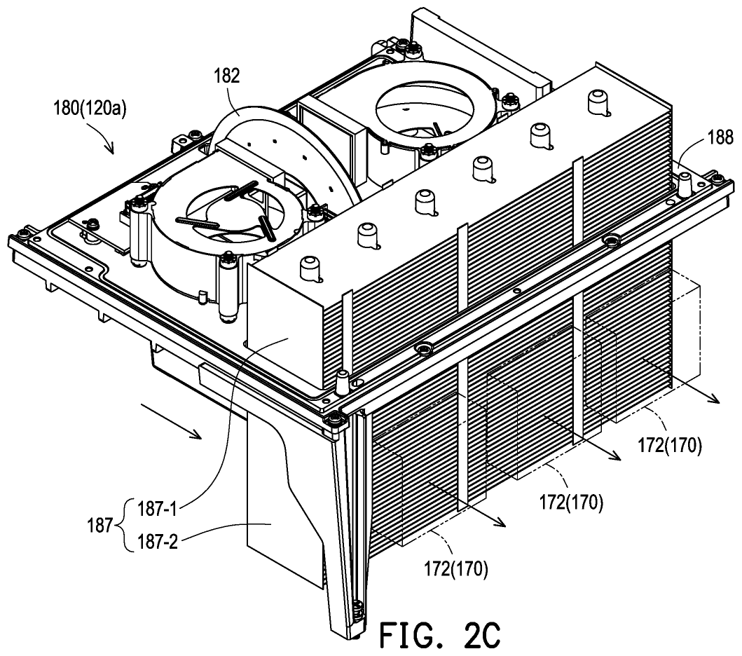

FIG. 2A is a top schematic diagram of a projection device according to another embodiment of the present invention. FIG. 2B is a rear schematic diagram of FIG. 2A. FIG. 2C is a three-dimensional schematic diagram of the light source module in FIG. 2A. For convenience of description, the first fan group and the second fan group in FIG. 2B are shown by dashed lines.

Referring to FIG. 1A and FIG. 2A at the same time, the projection device 100b of this embodiment is similar to the projection device 100a in FIG. 1A, but the difference between the two is that in this embodiment, the projection device 100b further includes a second fan group 170 disposed in the accommodating space S. The heat exchanger 142 is located between the first fan group 150 and the second fan group 170. In particular, there are no elements disposed between the second fan group 170 and the heat exchanger 142, so the volume of the projection device 100b is not increased due to the second fan group 170.

More specifically, please refer to FIG. 2A and FIG. 2B at the same time. In this embodiment, the second fan group 170 includes three second fans 172, and the second fans 172 are arranged along the direction A with the air outlet region facing the air outlet side plate 114. The air outlet region of the second fan group 170 faces the air outlet side plate 114 and corresponds to the air inlet region of the first fan group 150, in which the second fan group 170 and the first fan group 150 form a series flow field. Here, the orthographic projection area of the second fan group 170 on the air outlet side plate 114 is smaller than or equal to the orthographic projection area of the cooling fin set 143 of the heat exchanger 142 on the air outlet side plate 114. In one embodiment, the second fan 172 of the second fan group 170 may include at least one axial flow fan, and the axial direction Z of the axial flow fan may be parallel to the cooling air flow direction H in the cooling fin set 143. In another embodiment, at least one of the first fan 152 of the first fan group 150 and the second fan 172 of the second fan group 170 may include at least one axial flow fan, and the axial direction Z of the axial flow fan may be parallel to the cooling air flow direction H in the cooling fin set 143.

In addition, please refer to FIG. 2A and FIG. 2C at the same time. The wheel module 180 of the light source module 120a of this embodiment includes a phosphor wheel housing 188, a phosphor wheel 182, and a wheel cooling module 186. The wheel cooling module 186 includes a wheel cooling fin set 187, and the phosphor wheel 182 and a portion 187-1 of the wheel cooling fin set 187 are disposed in the phosphor wheel housing 188. Another portion 187-2 of the wheel cooling fin set 187 is disposed outside the phosphor wheel housing 188. Another portion 187-2 of the wheel cooling fin set 187 is adjacent to the air inlet region of the second fan group 170. Here, the wheel cooling module 186 corresponds to the second air inlet E21 of the first side plate 116.

In short, the projection device 100b of this example effectively increases the air volume flowing through the cooling fin set 143 of the heat exchanger 142 by disposing the second fan group 170, and may reduce the fan speed of the first fan group 150, thereby reducing the system noise of the projection device 100b. In addition, the wheel cooling fin set 187 disposed inside and outside the phosphor wheel housing 188 may increase the cooling efficiency of the heat exchanger 142, may effectively reduce the temperature in the phosphor wheel housing 188 and the phosphor wheel 182, and may also reduce the number of fans used, thereby reducing the system volume of the projection device 100b.

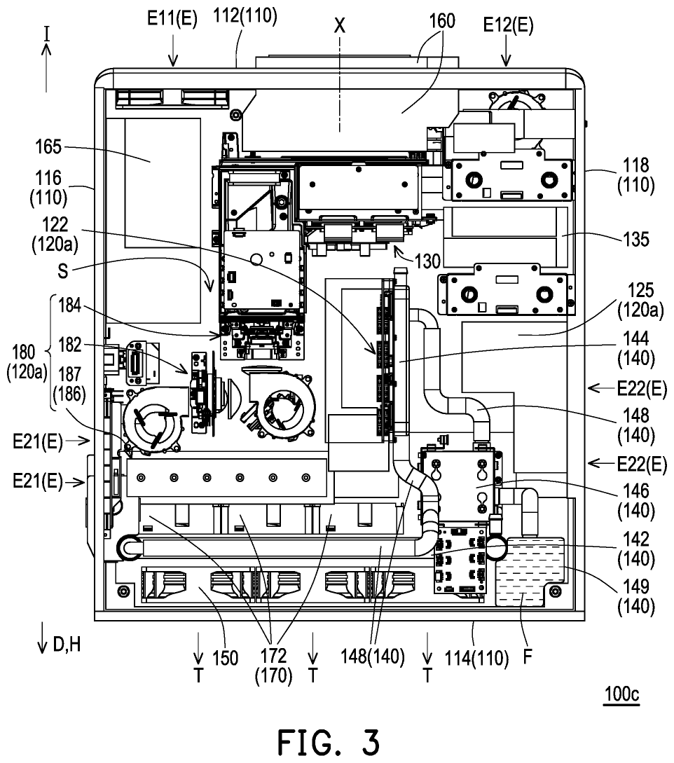

FIG. 3 is a top schematic diagram of a projection device according to another embodiment of the present invention. Referring to FIG. 2A and FIG. 3 at the same time, the projection device 100c of this embodiment is similar to the projection device 100b in FIG. 2A, but the difference between the two is that in this embodiment, the wheel module 180 of the light source module 120a of the projection device 100c further includes a filter wheel 184. The phosphor wheel 182 is located between the filter wheel 184 and the wheel cooling module 186. The second fan group 170 is located between the wheel cooling fin set 187 of the wheel cooling module 186 and the heat exchanger 142.

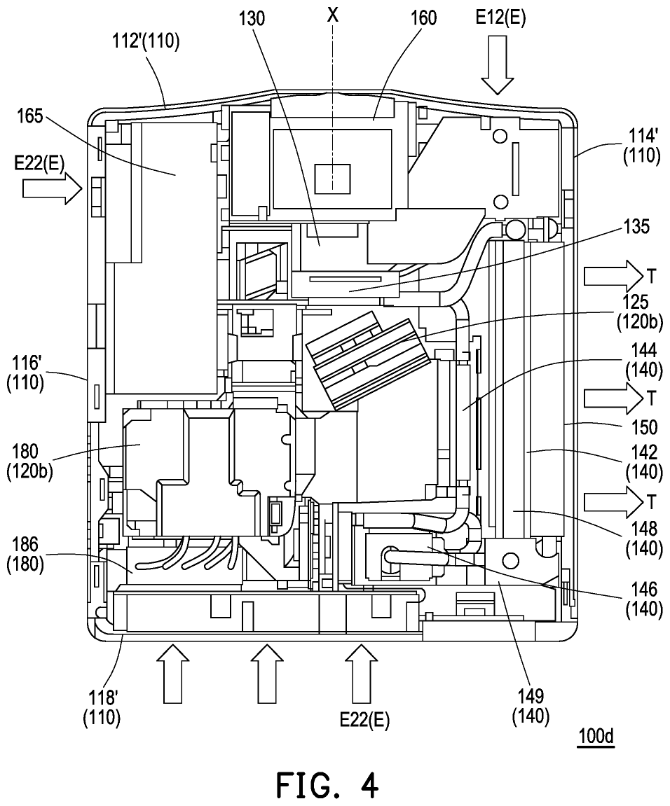

FIG. 4 is a top schematic diagram of a projection device according to another embodiment of the present invention. Referring to FIG. 1A and FIG. 4 at the same time, the projection device 100d of this embodiment is similar to the projection device 100a in FIG. 1A, but the difference between the two is that in this embodiment, the housing 110 of the projection device 100d includes a light emitting side plate 112′, an air outlet side plate 114′, a first side plate 116′, and a second side plate 118′. The second side plate 118′ and the light emitting side plate 112′ are located on opposite sides of the housing 110 and are both connected to the first side plate 116′ and the air outlet side plate 114′. The light emitting side plate 112′, the air outlet side plate 114′, the first side plate 116′, and the second side plate 118′ surround the accommodating space S, and the air outlet direction of the air flow from the air outlet T is not parallel to the light emitting direction of the image light beam from the projection lens 160. In this embodiment, the air outlet direction of the air outlet Tis perpendicular to the light emitting direction of the projection lens 160. There are multiple air inlets E, and the air inlet E includes a first air inlet E12 and multiple second air inlets E21 and E22. The first air inlet E12 is disposed on the light emitting side plate 112′ and is located on one side of the projection lens 160, the second air inlet E21 is disposed on the first side plate 116′, and the second air inlet E22 is disposed on the second side plate 118′. Preferably, the area of the first air inlet E12 plus the area of the second air inlets E21 and E22 is greater than the area of the air outlet T. The power module 165 of the projection device 100d is located between the projection lens 160 and the first side plate 116, and is adjacent to the second air inlet E21 disposed on the first side plate 116′. In addition, the heat exchanger 142 is located between the liquid cooling plate 144 of the liquid cooling module 140 and the first fan group 150. The wheel cooling module 186 corresponds to the second air inlet E22 of the second side plate 118′.

The heat exchanger 142 of the liquid cooling module 140 in this embodiment is adjacent to the air outlet T of the air outlet side plate 114, in which the first fan group 150 is located between the heat exchanger 142 and the air outlet T. With this design, it may ensure that all the air volume entering the projection device 100d passes through the cooling fin set of the heat exchanger 142 before being discharged out of the projection device 100d. That is to say, the aforementioned design may increase the cooling efficiency of the heat exchanger 142, so the projection device 100d of this embodiment may have better cooling effect, and thereby may have better image quality. Furthermore, through the optimized area design of the cooling fin set of the heat exchanger 142, the air outlet T and the air inlet E, the system volume of the projection device 100d of this embodiment may be effectively reduced.

In summary, the embodiments of the present invention have at least one of the following advantages or effects. In the design of the projection device of the present invention, the heat exchanger of the liquid cooling module is adjacent to the air outlet of the air outlet side plate and includes a cooling fin set. The first fan group is located between the heat exchanger and the air outlet, and the orthographic projection area of the cooling fin set of the heat exchanger on the air outlet side plate is smaller than or equal to the orthographic projection area of the first fan group on the air outlet side plate. With this design, it may ensure that the air volume entering the projection device passes through the cooling fin set of the heat exchanger before being discharged out of the projection device, so that the cooling fin set may obtain the maximum air volume of the system for cooling. Therefore, the projection device of the present invention may have better cooling effect, and thereby may have better image quality.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A projection device, comprising: a housing, a light source module, an optical engine module, a liquid cooling module, a first fan group, and a projection lens, wherein
the housing comprises a light emitting side plate, an air outlet side plate, a first side plate, and a second side plate, wherein the light emitting side plate, the air outlet side plate, the first side plate, and the second side plate surround an accommodating space;
the light source module, the optical engine module, the liquid cooling module, the first fan group, and at least a portion of the projection lens are disposed in the accommodating space;
the projection lens is disposed on the light emitting side plate, the air outlet side plate has an air outlet, and at least one of the light emitting side plate, the first side plate, and the second side plate has at least one air inlet; and
the liquid cooling module comprises a heat exchanger, the heat exchanger is adjacent to the air outlet of the air outlet side plate and comprises a cooling fin set, wherein the first fan group is located between the heat exchanger and the air outlet, and an orthographic projection area of the cooling fin set of the heat exchanger on the air outlet side plate is smaller than or equal to an orthographic projection area of the first fan group on the air outlet side plate.

2. The projection device according to claim 1, wherein the orthographic projection area of the first fan group on the air outlet side plate is equal to an area of the air outlet.

3. The projection device according to claim 1, wherein the air outlet side plate and the light emitting side plate are located on opposite sides of the housing and are both connected to the first side plate and the second side plate, and an air outlet direction of the air outlet is parallel to and opposite to an light emitting direction of the projection lens.

4. The projection device according to claim 1, further comprising:
a power module, disposed in the accommodating space, wherein the power module is located between the projection lens and the first side plate.

5. The projection device according to claim 4, further comprising:
an optical engine cooling module, disposed in the accommodating space and connected to the optical engine module, wherein the optical engine cooling module is located between the projection lens and the second side plate,
wherein the at least one air inlet is provided with the light emitting side plate, and the optical engine cooling module is disposed adjacent to the at least one air inlet provided with the light emitting side plate.

6. The projection device according to claim 3, wherein there is a plurality of the at least one air inlets, the air inlets comprises two first air inlets and a plurality of second air inlets, the two first air inlets are provided with the light emitting side plate and are respectively located on two sides of the projection lens, and the second air inlets are respectively disposed on the first side plate and the second side plate.

7. The projection device according to claim 6, wherein an area of the two first air inlets plus an area of the second air inlets is greater than an area of the air outlet.

8. The projection device according to claim 1, further comprising:
a second fan group, disposed in the accommodating space, wherein the heat exchanger is located between the first fan group and the second fan group, wherein there are no elements disposed between the second fan group and the heat exchanger.

9. The projection device according to claim 8, wherein an air outlet region of the second fan group faces the air outlet side plate and corresponds to an air inlet region of the first fan group.

10. The projection device according to claim 8, wherein an orthographic projection area of the second fan group on the air outlet side plate is smaller than or equal to the orthographic projection area of the cooling fin set of the heat exchanger on the air outlet side plate.

11. The projection device according to claim 8, wherein at least one of the first fan group and the second fan group comprises at least one axial flow fan, and an axial direction of the axial flow fan is parallel to a cooling air flow direction of the cooling fin set.

12. The projection device according to claim 11, wherein the heat exchanger further comprises at least one liquid flow pipe, the at least one liquid flow pipe is disposed in the cooling fin set, and a liquid flow direction of the at least one liquid flow pipe is perpendicular to the axial direction of the at least one axial flow fan.

13. The projection device according to claim 8, wherein the light source module comprises:
a wheel module, disposed in the accommodating space and adjacent to the first side plate, wherein the wheel module comprises a phosphor wheel and a wheel cooling module, the wheel cooling module is located between the phosphor wheel and the second fan group, the wheel cooling module comprises a wheel cooling fin set, and the second fan group is located between the wheel cooling fin set and the heat exchanger.

14. The projection device according to claim 6, wherein the light source module further comprises:
a light source driver, disposed in the accommodating space and connected to a light emitting element of the light source module, wherein the light source driver is adjacent to the second side plate.

15. The projection device according to claim 13, wherein the wheel module of the light source module further comprises a phosphor wheel housing, wherein the phosphor wheel is disposed in the phosphor wheel housing, a portion of the wheel cooling fin set is disposed in the phosphor wheel housing, another portion of the wheel cooling fin set is disposed outside the phosphor wheel housing, and the another portion of the wheel cooling fin set is adjacent to an air inlet region of the second fan group.

16. The projection device according to claim 1, wherein the liquid cooling module further comprises a liquid cooling plate, a driving element and a plurality of pipes, the heat exchanger, the liquid cooling plate and the driving element are connected to each other by the pipes to form a loop, and the liquid cooling plate is disposed adjacent to the light source module or the optical engine module to transfer heat generated by the light source module or the optical engine module to the heat exchanger through the loop.

17. The projection device according to claim 16, wherein the liquid cooling module further comprises an accommodating tank connected to the pipes and configured to accommodate a liquid medium, wherein the liquid medium in the accommodating tank is transferred into the pipes through the driving element.

18. The projection device according to claim 1, wherein an optical axis of the projection lens corresponds to a center point of the light emitting side plate of the housing.

19. The projection device according to claim 1, wherein
the light source module is configured to provide an illumination beam;
the optical engine is disposed on a transmission path of the illumination beam and configured to convert the illumination beam into an image light beam; and
the projection lens is disposed on a transmission path of the image light beam and configured to project the image light beam out of the projection device.

20. The projection device according to claim 1, wherein the second side plate and the light emitting side plate are located on opposite sides of the housing and are both connected to the first side plate and the air outlet side plate, and an air outlet direction of the air outlet is not parallel to an light emitting direction of the projection lens.

21. The projection device according to claim 20, wherein there is a plurality of the at least one air inlets, the air inlets comprises one first air inlet and a plurality of second air inlets, the first air inlet is provided with the light emitting side plate and is located on one side of the projection lens, and the second air inlets are respectively disposed on the first side plate and the second side plate.
